(19) United States
(12) Patent Application Publication
(10) Pub. No.: US 2013/0257703 A1
(43) Pub. Date: Oct. 3, 2013

(54) IMAGE DISPLAY SYSTEMS AND BI-DIRECTIONAL SHIFT REGISTER CIRCUITS

(71) Applicant: INNOLUX CORPORATION, Miao-Li County (TW)

(72) Inventor: Sheng-Feng HUANG, Miao-Li County (TW)

(73) Assignee: InnoLux Corporation, Miao-Li County (TW)

(21) Appl. No.: 13/804,295

(22) Filed: Mar. 14, 2013

(30) Foreign Application Priority Data
Mar. 30, 2012 (TW) 101111266

(51) Int. Cl. G11C 19/28; G09G 3/36; G11C 19/00

(52) U.S. Cl. CPC G11C 19/28; G11C 19/00; G09G 3/3611
USPC 345/100; 377/78; 377/79

(57) ABSTRACT

A bi-directional shift register circuit includes multiple stages of shift registers coupled in serial for generating multiple gate driving signals according to two clock signals. At least one of the shift registers includes a transmission gate and a latch. The transmission gate is turned on or off according to a start pulse of a start signal or a gate pulse of the gate driving signal output by at least one adjacent shift register, so as to output one of a first clock signal and a second clock signal as the corresponding gate driving signal. The latch is coupled to an output node for outputting the corresponding gate driving signal. The output node is further coupled to the transmission gate of at least one adjacent shift register.

### CROSS REFERENCE TO RELATED APPLICATIONS

This Application claims priority of Taiwan Patent Application No. 101111266, filed on Mar. 30, 2012, the entirety of which is incorporated by reference herein.

### BACKGROUND OF THE INVENTION

1. Field of the Invention

The invention relates to a shift register, and more particularly to a bi-directional shift register capable of operating in a forward direction and a reverse direction.

2. Description of the Related Art

Shift registers have been widely used in data driving circuits and gate driving circuits, for controlling timing in receiving data signals in each data line and for generating a scanning signal for each gate line, and the like. In a data driving circuit, a shift register outputs a selection signal so as to write an image signal into each data line. Meanwhile, in the gate driving circuit, the shift register outputs a scanning signal so as to sequentially write the image signal supplied to each data line into pixels in a pixel array.

A conventional shift register generates the selection signal or scanning signal in only a single direction. However, a single scanning direction does not satisfy the entire requirements of LCD products. For example, some display types of digital cameras are rotated according to the placement angle of the camera. In addition, some LCD monitors comprise the function of rotating the monitor, so an LCD display with different scanning turns is required. Therefore, a novel bi-directional shift register capable of outputting signals in a forward direction and a reverse direction is required.

### BRIEF SUMMARY OF THE INVENTION

Image display systems and bi-directional shift register circuits are provided. An exemplary embodiment of an image display system comprises a gate driving circuit for generating a plurality of gate driving signals according to two clock signals to drive a plurality of pixels in a pixel array. The gate driving circuit comprises a bi-directional shift register circuit, and the bi-directional shift register circuit comprises a plurality of stages of shift registers coupled in serial, each for generating one of the gate driving signals. At least one of the shift registers comprises an output node, a first input node, a second input node, a third input node, a transmission gate and a latch. The output node outputs the corresponding gate driving signal. The first input node is coupled to the output node of a first adjacent shift register for receiving the corresponding gate driving signal from the first adjacent shift register. The second input node is coupled to the output node of a second adjacent shift register for receiving the corresponding gate driving signal from the second adjacent shift register. The third input node receives one of a first clock signal and a second clock signal. The transmission gate is coupled to the first input node, the second input node, the third input node and the output node. The latch is coupled to the output node.

An exemplary embodiment of a bi-directional shift register circuit comprises multiple stages of shift registers coupled in serial for generating multiple gate driving signals according to two clock signals. At least one of the shift registers comprises a transmission gate and a latch. The transmission gate is turned on or off according to a start pulse of a start signal or a gate pulse of the gate driving signal output by at least one adjacent shift register, so as to output one of a first clock signal and a second clock signal as the corresponding gate driving signal. The latch is coupled to an output node for outputting the corresponding gate driving signal. The output node is further coupled to the transmission gate of at least one adjacent shift register.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows one of the various types of image display systems of the disclosure according to an embodiment of the disclosure;

FIG. 2 shows a structure of a bi-directional shift register circuit according to an embodiment of the disclosure;

FIG. 3 shows a circuit diagram of a shift register according to an embodiment of the disclosure;

FIG. 4 shows a circuit diagram of a shift register according to another embodiment of the disclosure;

FIG. 5 shows the waveforms of two reset signals according to an embodiment of the disclosure;

FIG. 6 shows a circuit diagram of an inverter according to an embodiment of the disclosure;

FIG. 7 shows a circuit diagram of a bi-directional shift register circuit according to an embodiment of the disclosure;

FIG. 8 shows the waveforms of the start signals, clock signals and gate driving signals in forward scan according to an embodiment of the disclosure;

FIG. 9 shows the waveforms of the start signals, clock signals and gate driving signals in reverse scan according to an embodiment of the disclosure;

FIG. 10 shows a circuit diagram of a bi-directional shift register circuit according to another embodiment of the disclosure;

FIG. 11 shows the waveforms of the start signals, clock signals and gate driving signals in forward scan according to another embodiment of the disclosure; and

FIG. 12 shows the waveforms of the start signals, clock signals and gate driving signals in reverse scan according to another embodiment of the disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

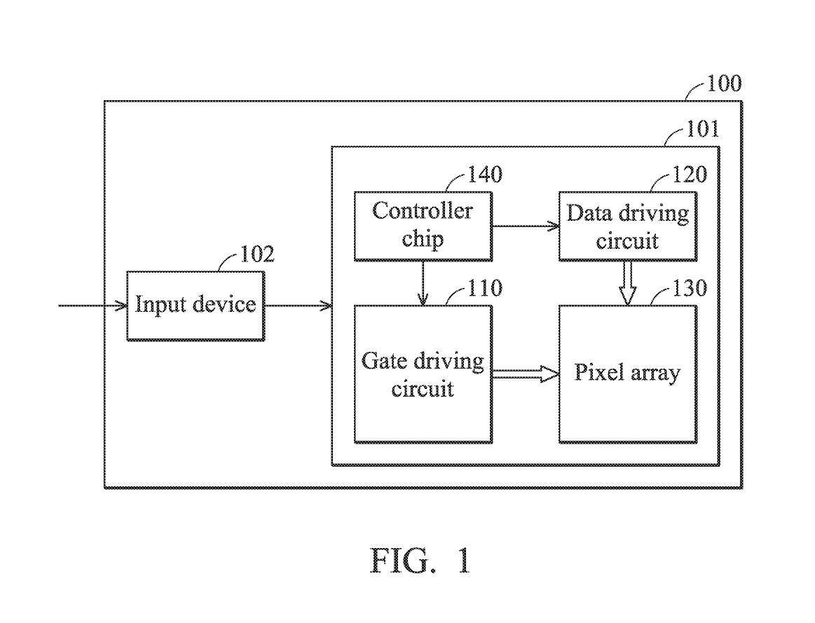

FIG. 1 shows one of the various types of image display systems of the disclosure according to an embodiment of the disclosure. As shown in FIG. 1, the image display system may comprise a display panel 101, where the display panel 101 may comprise a gate driving circuit 110, a data driving circuit 120, a pixel array 130 and a controller chip 140. The gate driving circuit 110 generates a plurality of gate driving signals to drive a plurality of pixels in the pixel array 130. The data driving circuit 120 generates a plurality of data driving signals to provide data to the pixels of the pixel array 130. The controller chip 140 generates a plurality of timing signals, comprising clock signals, reset signals and start signals.

In addition, the image display system of the disclosure may further be comprised in an electronic device 100. The electronic device 100 may comprise the above-mentioned display panel 101 and an input device 102. The input device 102 receives image signals and controls the display panel 101 to display images. According to an embodiment of the disclosure, the electronic device 100 may be implemented as various devices, comprising: a mobile phone, a digital camera, a personal digital assistant (PDA), a lap-top computer, a personal computer, a television, an in-vehicle display, a portable DVD player, or any apparatus with image display functionality.

According to an embodiment of the disclosure, the gate driving circuit 110 may comprise a bi-directional shift register circuit capable of sequentially generating a corresponding gate driving signal to each gate line in different scan directions (for example, forward scan direction and reverse scan direction), so as to write the image signal provided to each data line to the pixels in the pixel array 130.

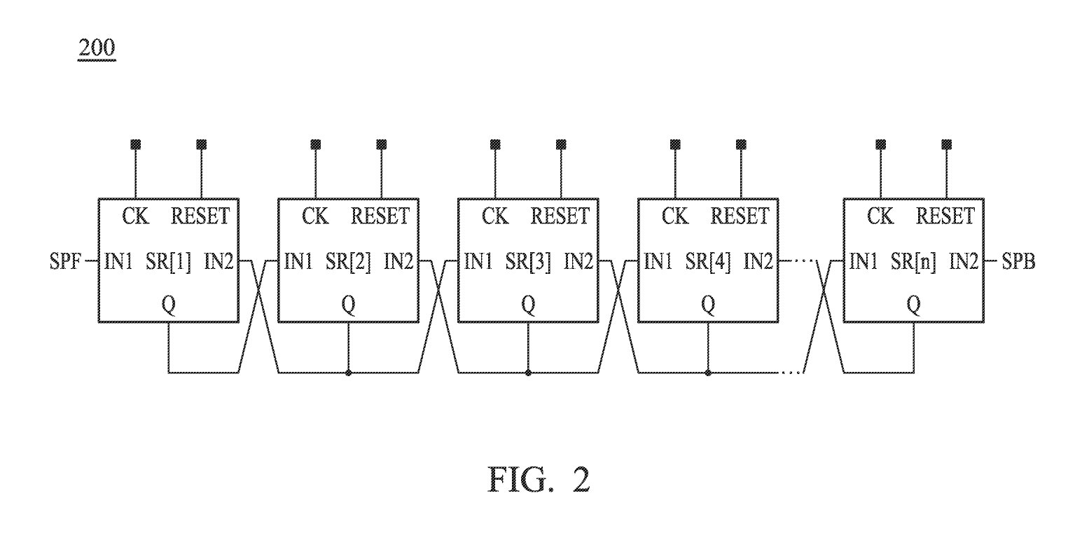

FIG. 2 shows a structure of a bi-directional shift register circuit according to an embodiment of the disclosure. The bi-directional shift register circuit 200 comprises a plurality of stages of shift registers SR[1], SR[2], SR[3], SR[4] . . . SR[n] coupled in serial for generating a plurality of gate driving signals according to two clock signals CK1 and CK2. Each shift register comprises input nodes IN1, IN2, CK and RESET and output nodes Q and QB (not shown in FIG. 2), where the output node Q and/or QB is/are operative to output the corresponding gate driving signal of each shift register and the signals outputted by the output nodes Q and QB are complementary to each other. Note that in the embodiments of the disclosure, the output node Q of each shift register is further coupled to at least one adjacent shift register for transmitting the corresponding gate driving signal to the adjacent shift register.

As shown in FIG. 2, the first stage of shift register SR[1] receives the start signal SPF via the input node IN1, and the input node IN1 of the remaining stages of shift registers SR[2]˜SR[n] is coupled to the output node Q of an adjacent shift register (for example, a previous stage of shift register SR[1]˜SR[n-1]) for receiving the corresponding gate driving signal from that shift register. The other input node IN2 of the shift registers SR[1]˜SR[n-1] is coupled to the output node Q of another adjacent shift register (for example, a next stage of shift register SR[2]˜SR[n]) for receiving the corresponding gate driving signal from that shift register. The last stage of shift register SR[n] receives another start signal SPB via the input node IN2.

In addition, each shift register further receive one of the clock signals CK1 and CK2 via the input node CK. In the embodiments of the disclosure, as shown in FIG. 2, when a shift register receives the clock signal CK1, at least one shift register adjacent to that shift register receives the clock signal CK2. In other words, the clock signals CK1 and CK2 are supplied to the shift registers SR[1]˜SR[n] in turn. The proposed bi-directional shift register circuit will be further illustrated in the following paragraphs.

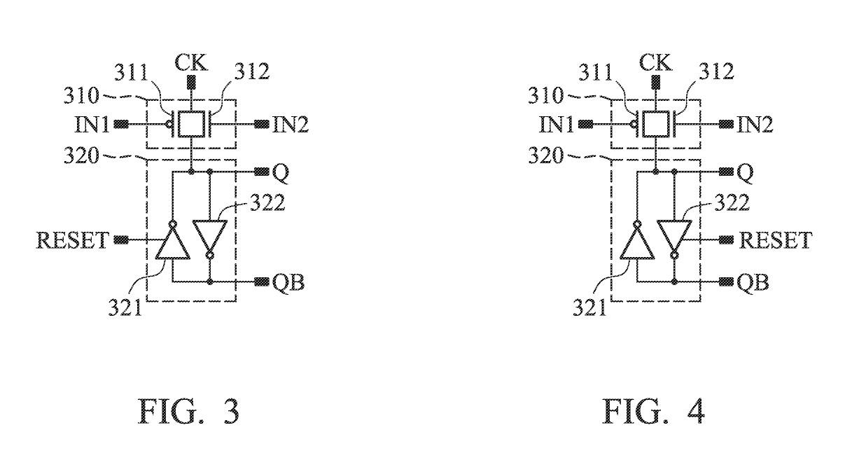

FIG. 3 shows a circuit diagram of a shift register according to an embodiment of the disclosure. As shown in FIG. 3, the shift register may comprise a transmission gate 310 and a latch 320. The transmission gate 310 is coupled to the input nodes IN1, IN2 and CK and the output node Q. The latch 320 is coupled to the input node RESET and the output nodes Q and QB, where the signals outputted by the output node Q and QB are complementary to each other.

According to an embodiment of the disclosure, the transmission gate 310 may be turned on or off according to a start pulse of the start signal or a gate pulse of the gate driving signal output by at least an adjacent shift register, for outputting the clock signal CK1 or CK2 at the output node Q as the corresponding gate driving signal. The latch 320 is also coupled to the output node Q for latching and outputting the corresponding gate driving signal.

The transmission gate 310 may comprise two transistors 311 and 312, wherein the transistor 311 and 312 are respectively turned on or off according to the signals respectively received at the input nodes IN1 and IN2. When the transistor 311 is turned on, the shift register is set to a first state. When the transistor 312 is turned on, the shift register is set to a second state. The latch 320 may comprise two inverters 321 and 322 and receive the reset signal through one of the inverters 321 and 322 for resetting (or initializing) a voltage at the output node Q or QB. FIG. 4 shows a circuit diagram of a shift register according to another embodiment of the disclosure. The shift register shown in FIG. 4 is similar to the shift register shown FIG. 3, and the only difference is that in the embodiment shown in FIG. 4, the latch 320 receives the reset signal through the inverter 322.

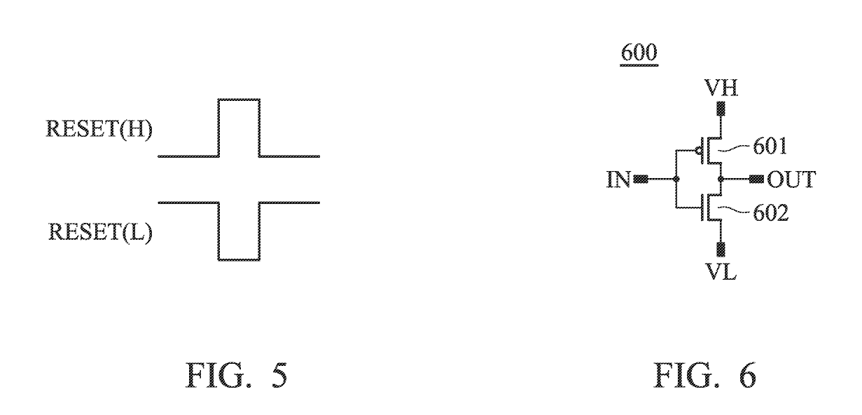

In the embodiments of the disclosure, the designer may flexibly choose the inverter 321 or 322 to receive the reset signal according to the reset (or initial) requirements. For example, when the voltage at the output node Q is reset (or initialized) to a high voltage, the designer may choose the inverter 321 to receive the reset signal RESET(H) as shown in FIG. 5. The reset signal RESET(H) may comprise an active high pulse for resetting (or initializing) the voltage at the output node Q to a high voltage.

In addition, the designer may also choose the inverter 322 to receive another reset signal RESET(L) as shown in FIG. 5. The reset signal RESET(L) may comprise an active low pulse for resetting (or initializing) the voltage at the output node QB to a low voltage. The same result as resetting (or initializing) the voltage at the output node Q to a high voltage may be achieved by resetting (or initializing) the voltage at the output node QB to a low voltage.

FIG. 6 shows a circuit diagram of an inverter according to an embodiment of the disclosure. The inverter 600 may comprise two transistors 601 and 602. When the inverter 600 is implemented as the inverter 322, the input node IN of the inverter 600 is coupled to the output node Q and the output node OUT of the inverter 600 is coupled to the output node QB. When the inverter 600 is implemented as the inverter 321, the input node IN of the inverter 600 is coupled to the output node QB and the output node OUT of the inverter 600 is coupled to the output node Q.

Besides the input node IN, the inverter 600 may further comprise two input nodes VH and VL for receiving two different operation voltages. According to an embodiment, the reset signal RESET(L) having an active low pulse may be inputted to the input node VH of the inverter 600 when resetting or initializing the voltage at the output node OUT of the inverter, for resetting or initializing the voltage at the output node OUT to a low voltage. Similarly, the reset signal RESET(H) having an active high pulse may also be inputted to the input node VL of the inverter 600 for resetting or initializing the voltage at the output node OUT to a high voltage.

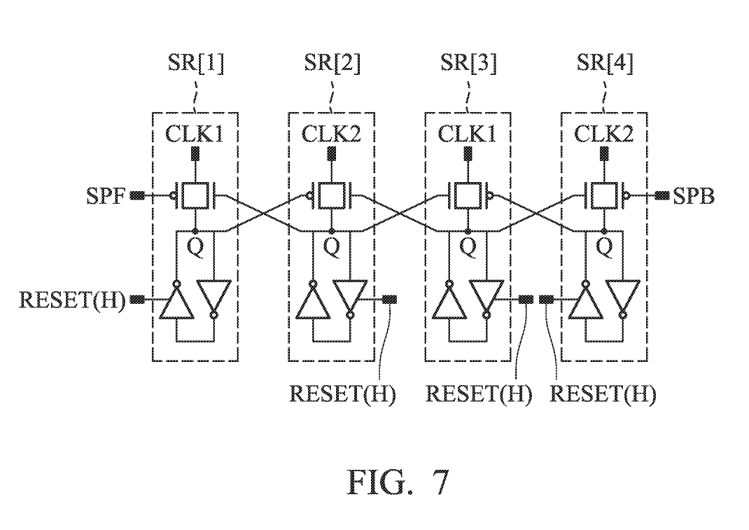

FIG. 7 shows a circuit diagram of a bi-directional shift register circuit according to an embodiment of the disclosure. For simplicity, FIG. 7 shows a bi-directional shift register circuit having four stages of shift registers coupled in serial. However, it is noted that the bi-directional shift register circuit may also comprise more than four stages of shift registers as shown in FIG. 1 and the disclosure should not be limited thereto.

According to an embodiment of the disclosure, in forward scan, the first stage of shift register SR[1] receives the start signal SPF and the shift registers SR[1]˜SR[4] sequentially output the corresponding gate driving signal Q(1)˜Q(4) at the output node Q in a first order. In reverse scan, the last stage of shift register SR[4] receives the start signal SPB and the shift registers SR[4]˜SR[1] sequentially output the corresponding gate driving signal Q(4)˜Q(1) at the output node Q in a second order. Note that in the embodiment of the disclosure, by controlling the timing of the start pulses of the start signals SPF and SPB, the scan direction may be switched. In other words, there is no need to use an extra switch for switching the scan direction in the proposed bi-directional shift register circuit, and therefore, circuit area can be saved.

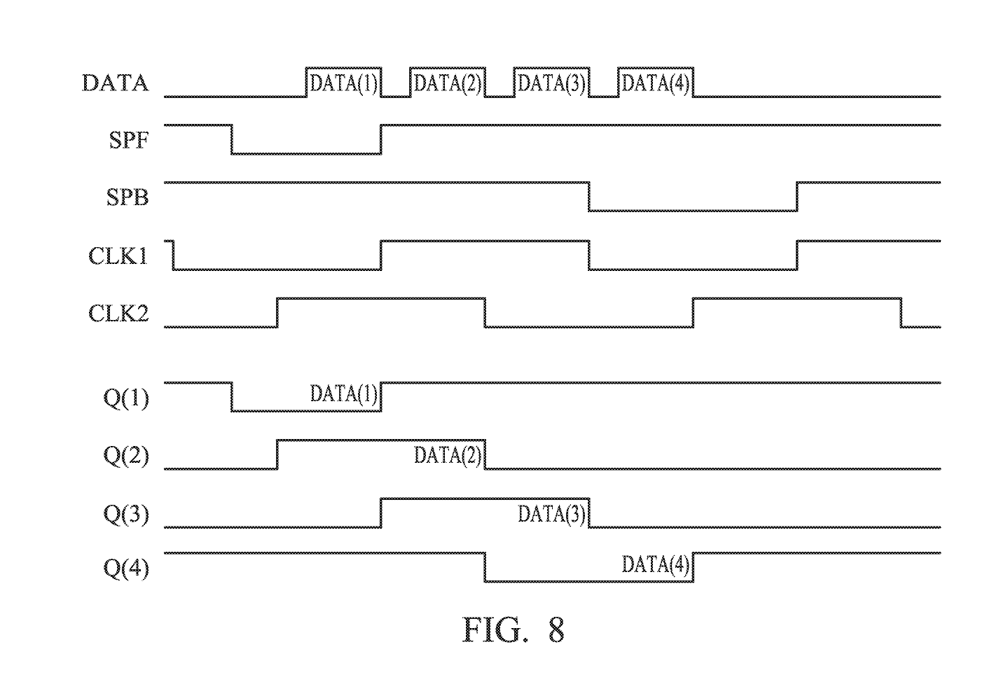

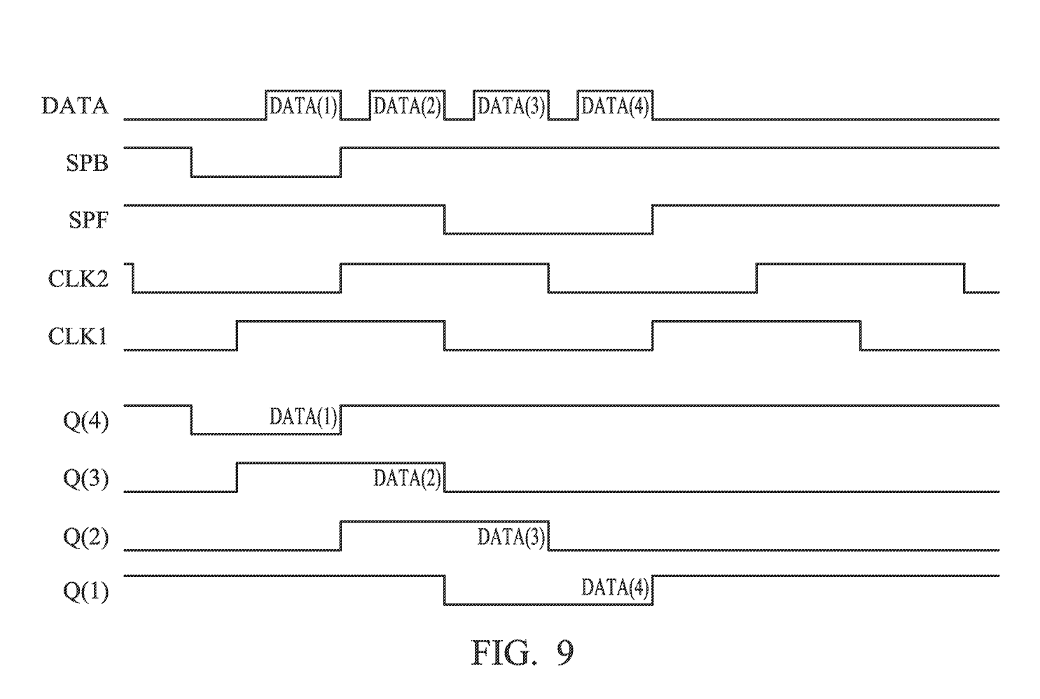

FIG. 8 shows the waveforms of the start signals, clock signals and gate driving signals in forward scan according to an embodiment of the disclosure. FIG. 9 shows the waveforms of the start signals, clock signals and gate driving signals in reverse scan according to an embodiment of the disclosure. Accompanying FIG. 7, FIG. 8 and FIG. 9, the operation of the proposed bi-directional shift register circuit may be further introduced in the following paragraphs.

As shown in FIG. 7, except for the first and last stages of shift register, input nodes of the remaining shift registers are respectively coupled to the output nodes Q of a previous stage and a following stage of shift registers for turning on or off the transmission gate according to the gate driving signals output by the adjacent shift registers. When the transmission gate is turned on, the clock signals CK1 and CK2 may be passed to the output node Q and may further be passed to the input node of the transmission gate of the adjacent shift register for turning on or off the transmission gate of the adjacent shift register.

Note that only two clock signals are required in the proposed bi-directional shift register circuit to generate the corresponding gate driving signals. As shown in FIG. 8 and FIG. 9, the clock signal CK1 may comprise a plurality of clock pulses and the clock signal CK2 may also comprise a plurality of clock pulses. According to an embodiment of the disclosure, the edges of the clock pulses of the clock signal CK1 and the edges of the clock pulses of the clock signal CK2 are interleaved. In other words, the edges (including the rising edge and falling edge) of the clock pulses of the clock signal CK1 do not align with the edges (including the rising edge and falling edge) of the clock pulses of the clock signal CK2, but occur during the high or low intervals of the clock pulses of the clock signal CK2.

In addition, note that in the embodiments of the disclosure, the type of transistor adopted in the transmission gate of each shift register may be decided according to the waveform of the clock signal CK1/CK2 received by the shift register. Suppose that the transmission gate of each shift register comprises transistors T1 and T2. Transistor T1 is coupled to the output node Q of a previous stage of shift register (or, for the first stage of shift register, the transistor T1 is coupled to the start signal SPF). Transistor T2 is coupled to the output node Q of a following stage of shift register (or, for the last stage of shift register, the transistor T2 is coupled to the start signal SPB).

When the start pulse or the gate pulse received by the transistor T1 is an active low pulse (that is, having low voltage level during the active period), the transistor T1 may be selected as a PMOS transistor and the other transistor T2 in the transmission gate may be selected as an NMOS transistor. On the other hand, when the start pulse or the gate pulse received by the transistor T1 is an active high pulse (that is, having high voltage level during the active period), the transistor T1 may be selected as an NMOS transistor and the other transistor T2 in the transmission gate may be selected as a PMOS transistor.

For example, as shown in FIG. 7 and FIG. 8, because the start signal SPF is an active low signal having an active low start pulse, the transistor in the shift register SR[1] receiving the start signal SPF may be a PMOS transistor. For another example, because the gate driving signal Q(2) is an active high signal having an active high gate pulse, the transistors in the shift registers SR[1] and SR[3] receiving the gate driving signal Q(2) may be an NMOS transistor.

In addition, note that as shown in FIG. 8 and FIG. 9, each gate driving signal Q(1)˜Q(4) may respectively comprise a gate pulse. A leading edge and a trailing edge of the gate pulse may align with a leading edge and a trailing edge of one of a plurality of clock pulses comprised in the clock signal CK1/CK2 received by the shift register. For example, a leading edge and a trailing edge of the gate pulse of the gate driving signal Q(2) may align with a leading edge and a trailing edge of the first clock pulse of the clock signal CK2, a leading edge and a trailing edge of the gate pulse of the gate driving signal Q(4) may align with a leading edge and a trailing edge of the second clock pulse of the clock signal CK2, and so on.

According to an embodiment of the disclosure, an initial voltage at the output node Q of each stage of shift register may be decided according to whether the aligned leading edge of the clock pulse is a rising edge or falling edge. For example, as shown in FIG. 8, because the leading edge of the first clock pulse of the clock signal CK2 is a rising edge, the initial voltage at the output node Q of the shift register SR[2] may be reset to a low voltage. For another example, because the leading edge of the second clock pulse of the clock signal CK2 is a falling edge, the initial voltage at the output node Q of the shift register SR[4] may be reset to a high voltage.

Note that as shown in FIG. 8 and FIG. 9, in the embodiments of the disclosure, the waveforms of each two gate pulses overlap with each other so that the active period of a gate pulse covers two data in the data signal DATA. However, because the gate pulse is ended when the corresponding data DATA(1)˜DATA(4) arrives, the pixel can still receive correct data, which is shown as the data DATA(1)˜DATA(4) labeled on the corresponding gate driving signal Q(1)˜Q(4) in FIG. 8 and FIG. 9.

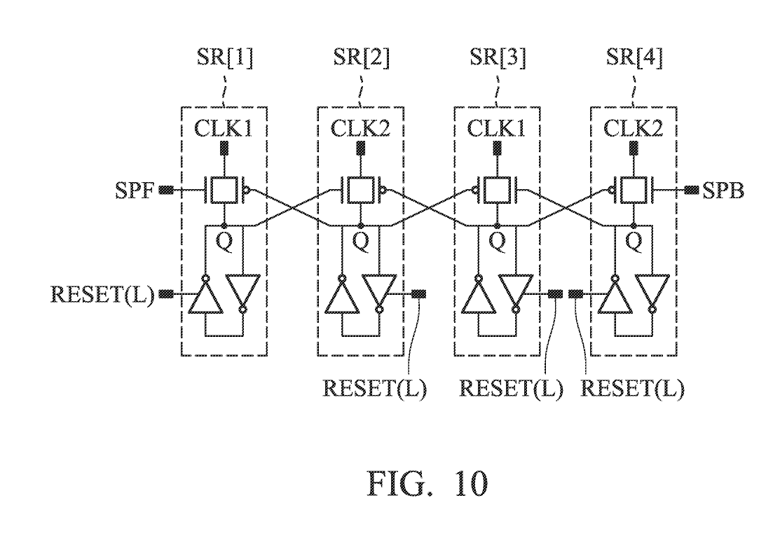

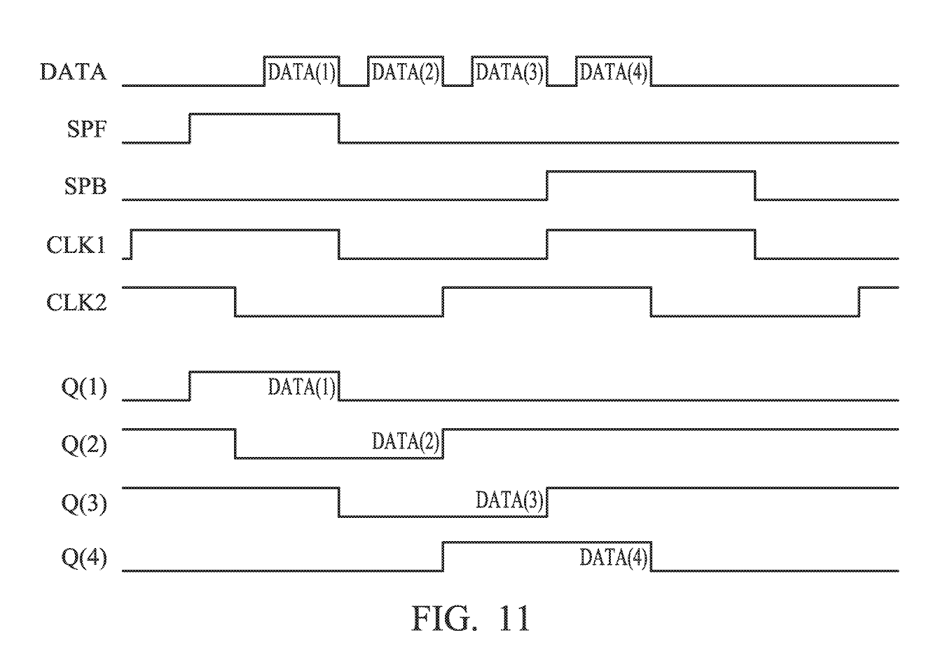

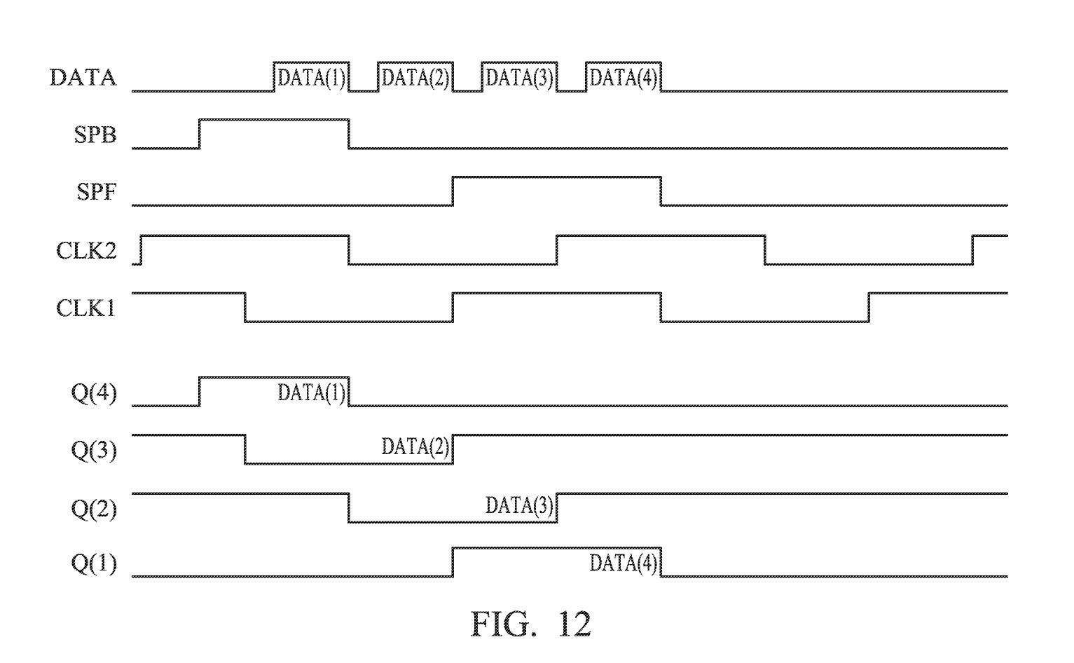

FIG. 10 shows a circuit diagram of a bi-directional shift register circuit according to another embodiment of the disclosure. In the embodiment, the transistor type in the transmission gate in each stage of shift register is different from the embodiment shown in FIG. 7. In addition, in the embodiment, the initial voltage at the output node Q of each stage of shift register is reset according to the reset signal RESET(L). FIG. 11 shows the waveforms of the start signals, clock signals and gate driving signals in forward scan according to another embodiment of the disclosure. FIG. 12 shows the waveforms of the start signals, clock signals and gate driving signals in reverse scan according to another embodiment of the disclosure. The signal waveforms shown in FIG. 11 and FIG. 12 are the corresponding waveforms of the signals of the bi-directional shift register circuit shown in FIG. 10.

Note that one skilled in the art can derive a bi-directional shift register circuit having a structure different from the ones shown in FIG. 7 and FIG. 10 according to the concepts of the disclosure as illustrated above. Therefore, the disclosure should not be limited to the circuit structures as shown in FIG. 7 and FIG. 10. In addition, in the embodiment of the disclosure, the bi-directional shift register circuit may comprise at least four stages of shift registers coupled in serial, wherein the amount of shift registers is preferably a multiple of four.

As previously described, only two clock signals are required in the proposed bi-directional shift register circuit to generate the corresponding gate driving signals. Therefore, the amount of clock signals required in the proposed bi-directional shift register circuit may be fewer than the conventional design. In addition, as previously described, in the embodiment of the disclosure, the scan direction may be easily switched by controlling the timing of the start pulses of the start signals SPF and SPB. Therefore, there is no need to use an extra switch for switching the scan direction in the proposed bi-directional shift register circuit, and therefore, circuit area can be saved.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. An image display system, comprising:
a gate driving circuit, for generating a plurality of gate driving signals according to two clock signals to drive a plurality of pixels in a pixel array, wherein the gate driving circuit comprises a bi-directional shift register circuit, the bi-directional shift register circuit comprises a plurality of stages of shift registers coupled in serial for generating one of the gate driving signals respectively, and wherein at least one of the shift registers comprises;
an output node, for outputting the corresponding gate driving signal;
a first input node, coupled to the output node of a first adjacent shift register for receiving the corresponding gate driving signal from the first adjacent shift register;
a second input node, coupled to the output node of a second adjacent shift register for receiving the corresponding gate driving signal from the second adjacent shift register;
a third input node, for receiving one of a first clock signal and a second clock signal;
a transmission gate, coupled to the first input node, the second input node, the third input node and the output node; and
a latch, coupled to the output node.

2. The image display system as claimed in claim 1, further comprising a display panel, wherein the display panel comprises:
the gate driving circuit;
the pixel array, comprising the pixels;
a data driving circuit, for generating a plurality of data driving signals to provide data to the pixels in the pixel array; and
a controller chip, for generating the first clock signal, the second clock signal and a start signal.

3. The image display system as claimed in claim 2, wherein in forward scan, a first stage of shift register receives the start signal and the shift registers sequentially output the corresponding gate driving signal at the output node in a first order, and in reverse scan, a last stage of shift register receives the start signal and the shift registers sequentially output the corresponding gate driving signal at the output node in a second order.

4. The image display system as claimed in claim 1, wherein the first clock signal comprises a plurality of first clock pulses, the second clock signal comprises a plurality of second clock pulses, and a plurality of edges of the first clock pulses and a plurality of edges of the second clock pulses are interleaved.

5. The image display system as claimed in claim 1, wherein the transmission gate comprises:
a first transistor, coupled to the first input node, the third input node and the output node; and
a second transistor, coupled to the second input node, the third input node and the output node,
wherein when a gate pulse of the gate driving signal received at the first input node is an active low pulse, the first transistor is a P-type transistor and the second transistor is an N-type transistor, and when a gate pulse of the gate driving signal received at the first input node is an active high pulse, the first transistor is an N-type transistor and the second transistor is a P-type transistor.

6. The image display system as claimed in claim 1, wherein the latch further receives a reset signal for resetting voltage at the output node.

7. The image display system as claimed in claim 6, wherein each of the gate driving signals comprises at least one gate pulse, a leading edge and a trailing edge of the gate pulse align with a leading edge and a trailing edge of one of a plurality of clock pulses comprised in the first clock signal or the second clock signal.

8. The image display system as claimed in claim 7, wherein when the leading edge of the clock pulse which aligns with the gate pulse output by one of the shift registers is a rising edge, the voltage at the output node of the shift register is reset to a low voltage, and when the leading edge of the clock pulse is a falling edge, the voltage at the output node of the shift register is reset to a high voltage, and wherein a level of the high voltage is higher than that of the low voltage.

9. The image display system as claimed in claim 6, wherein the latch comprises:
a first inverter; and
a second inverter, wherein one of the first inverter and the second inverter receives the reset signal.

10. The image display system as claimed in claim 1, wherein the bi-directional shift register circuit comprises four stages of shift registers coupled in serial.

11. The image display system as claimed in claim 1, wherein an amount of the shift registers is a multiple of four.

12. A bi-directional shift register circuit, comprising a plurality of stages of shift registers coupled in serial for generating a plurality of gate driving signals according to two clock signals, wherein at least one of the shift registers comprises:
a transmission gate, turned on or off according to a start pulse of a start signal or a gate pulse of the gate driving signal output by at least one adjacent shift register so as to output one of a first clock signal and a second clock signal as the corresponding gate driving signal; and
a latch, coupled to an output node for outputting the corresponding gate driving signal, wherein the output node is further coupled to the transmission gate of at least one adjacent shift register.

13. The bi-directional shift register circuit as claimed in claim 12, wherein when one of the shift registers receives the first clock signal, at least one shift register adjacent to the one of the shift registers receives the second clock signal.

14. The bi-directional shift register circuit as claimed in claim 12, wherein in forward scan, a first stage of shift register receives the start pulse and the shift registers sequentially output the corresponding gate driving signal in a first order, and in reverse scan, a last stage of shift register receives the start pulse and the shift registers sequentially output the corresponding gate driving signal in a second order.

15. The bi-directional shift register circuit as claimed in claim 12, wherein the first clock signal comprises a plurality of first clock pulses, the second clock signal comprises a plurality of second clock pulses, and a plurality of edges of the first clock pulses and a plurality of edges of the second clock pulses are interleaved.

16. The bi-directional shift register circuit as claimed in claim 12, wherein the transmission gate comprises:
a first transistor; and
a second transistor,
wherein when the first transistor is a P-type transistor, the second transistor is an N-type transistor and when the first transistor is an N-type transistor, the second transistor is a P-type transistor.

17. The bi-directional shift register circuit as claimed in claim 12, wherein the latch further receives a reset signal for resetting a voltage at the output node.

18. The bi-directional shift register circuit as claimed in claim 17, wherein each of the gate driving signals comprises at least one gate pulse, a leading edge and a trailing edge of the gate pulse align with a leading edge and a trailing edge of one of a plurality of clock pulses comprised in the first clock signal or the second clock signal.

19. The bi-directional shift register circuit as claimed in claim 17, wherein when the leading edge of the clock pulse which aligns with the gate pulse output by one of the shift registers is a rising edge, the voltage at the output node of the shift register is reset to a low voltage, and when the leading edge of the clock pulse is a falling edge, the voltage at the output node of the shift register is reset to a high voltage.

20. The bi-directional shift register circuit as claimed in claim 17, wherein the latch comprises:
a first inverter; and
a second inverter, wherein one of the first inverter and the second inverter receives the reset signal.

21. The bi-directional shift register circuit as claimed in claim 12, wherein an amount of the shift registers is a multiple of four.
